(19) United States
(12) Patent Application Publication
(10) Pub. No.: US 2026/0296243 A1
(43) Pub. Date: Oct. 1, 2026

(54) ELECTRICAL ISOLATION MONITORING

(71) Applicant: Rivian IP Holdings, LLC, Irvine, CA (US)

(72) Inventors: Adam John Emes, Los Angeles, CA (US); Lixiang Wei, Irvine, CA (US)

(21) Appl. No.: 19/093,439

(22) Filed: Mar. 28, 2025

(51) Int. Cl. B60L 53/62; B60L 53/18; G01R 31/40; H03G 3/30

(52) U.S. Cl. CPC B60L 53/62; B60L 53/18; G01R 31/40; H03G 3/30; H03G 2201/103

(57) ABSTRACT

Systems, methods, and electric vehicle chargers are provided for isolation monitoring. A system includes a high voltage bus, an adjustable gain amplifier having an input coupled to the high voltage bus and having an output, where the adjustable gain amplifier is configured to generate an amplified signal, control circuitry configured to select a gain of the adjustable gain amplifier based on a voltage of the high voltage bus, and isolation detection circuitry coupled to the output of the adjustable gain amplifier and configured to determine, based on the amplified signal, whether the high voltage bus is electrically isolated.

### INTRODUCTION

Power delivery equipment may include electrical isolation monitoring to avoid having electrical power flow through unintended current paths. For example, a high-voltage vehicle charger (e.g., for an electric vehicle or any other electric mobility device) may include an isolation monitoring system that checks for whether a high-voltage bus of the charger (or the high voltage across a battery of an electric vehicle) is electrically isolated from a reference voltage (e.g., ground). That is, the isolation monitoring system may check for how much resistance is present between the high voltage bus (or high voltage battery) and ground. Ensuring that electrical isolation is maintained may support successful power delivery. It is desirable to rapidly check for electrical isolation, e.g., to provide fast “plug-to-charge” times and to identify any possible reduction in the isolation resistance before significant current begins to flow through an unintended current path.

### SUMMARY

A vehicle charger may include an isolation monitoring system that is electrically coupled to a high voltage bus (e.g., which is configured to charge a battery of a vehicle). Isolation monitoring systems with static amplifiers (e.g., that are configured to provide a single gain value) may exhibit isolation detection speed that varies with the voltage of the high voltage bus, which may depend on the state-of-charge of an electric vehicle, the state of a power delivery network, an amount of time that the bus has been charging, a condition of the power equipment, any other factors, or any combination thereof. Under some conditions, such isolation monitoring systems may not be sufficiently fast, which increases “plug-to-charge” time and which may not respond to a possible loss of isolation sufficiently quickly. While it may be possible to increase the speed of such isolation monitoring systems using digital circuitry (e.g., an analog-to-digital converter (ADC) with more bits), improving signals in the analog domain may be more power-efficient and may provide resilience to varying power and environmental conditions.

To provide faster isolation monitoring without requiring increased ADC resolution, an isolation monitoring system includes an adjustable gain amplifier that is electrically coupled to a high voltage bus or a high voltage battery. The gain of the adjustable gain amplifier is selected based on a voltage of the high voltage bus or battery, such that isolation detection circuitry may quickly determine whether the high voltage is electrically isolated based on the output of the adjustable gain amplifier.

In accordance with some embodiments of the present disclosure, systems, methods, and electric vehicle chargers are provided for isolation monitoring. A system includes a high voltage bus, an adjustable gain amplifier having an input coupled to the high voltage bus and having an output, where the adjustable gain amplifier is configured to generate an amplified signal, control circuitry configured to select a gain of the adjustable gain amplifier based on a voltage of the high voltage bus, and isolation detection circuitry coupled to the output of the adjustable gain amplifier and configured to determine, based on the amplified signal, whether the high voltage bus is electrically isolated.

In some embodiments, the adjustable gain amplifier includes a multiplexer and a plurality of resistors, wherein the control circuitry is configured to cause the multiplexer to select a first resistor of the plurality of resistors when the voltage is in a first range, and to select a second resistor of the plurality of resistors when the voltage is in a second range, the second resistor having a greater resistance than the first resistor and the second range being less than the first range.

In some embodiments, the control circuitry is further configured to cause the multiplexer to select a third resistor of the plurality of resistors when the voltage is in a third range, the third resistor having a greater resistance than the second resistor and the third range being less than the second range.

In some embodiments, the system further includes a relay, wherein the control circuitry is configured to cause the relay to couple the high voltage bus to an electric vehicle (e.g., to charge a battery of the electric vehicle) in response to a determination that the high voltage bus is electrically isolated.

In some embodiments, the adjustable gain amplifier is a first adjustable gain amplifier, the amplified signal is a first amplified signal, the control circuitry is first control circuitry, and the first adjustable gain amplifier and the first control circuitry are coupled to a first supply voltage. The system also includes a second adjustable gain amplifier configured to generate a second amplified signal, and second control circuitry coupled to the high voltage bus and coupled to a second supply voltage, equal and opposite to the first supply voltage. The isolation detection circuitry is further configured to determine whether the high voltage bus is electrically isolated based on the second amplified signal.

In some embodiments, the isolation detection circuitry includes an analog-to-digital converter (ADC) configured to sample the amplified signal of the adjustable gain amplifier, and processing circuitry configured to fit a reference curve to at least three samples of the ADC, where determining whether the high voltage bus is electrically isolated is based on the fitted reference curve.

In some embodiments, the at least three samples of the ADC are selected as a first three uniquely valued samples of the ADC.

In some embodiments, the processing circuitry is further configured to determine that an arc event has occurred based on a failure to fit the at least three samples of the ADC to the reference curve.

### BRIEF DESCRIPTION OF THE DRAWINGS

The above and other objects and advantages of the disclosure will be apparent upon consideration of the following detailed description, taken in conjunction with the accompanying drawings, in which like reference characters refer to like parts throughout, and in which:

FIG. 1A shows an illustrative block diagram of a residential electric vehicle charging system including isolation monitoring circuitry and bidirectional charging capabilities, in accordance with some embodiments of the present disclosure;

FIG. 1B shows an illustrative block diagram depicting how on-site power generation equipment can be added to the residential electric vehicle charging system of FIG. 1A, in accordance with some embodiments of the present disclosure;

FIG. 1C shows an illustrative block diagram depicting how an isolation monitoring device can be added to other equipment of the residential electric vehicle charging system of FIG. 1A, in accordance with some embodiments of the present disclosure;

FIG. 1D shows an illustrative block diagram of a power system coupled to an electric vehicle charger including isolation monitoring circuitry, in accordance with some embodiments of the present disclosure;

FIG. 2 shows an illustrative block diagram of isolation monitoring circuitry including an adjustable gain amplifier that amplifies a signal from a high voltage bus and provides the amplified signal to isolation detection circuitry, in accordance with some embodiments of the present disclosure;

FIG. 3 shows an illustrative block diagram of isolation detection circuitry configured to detect isolation based on positive and negative input signals, in accordance with some embodiments of the present disclosure;

FIG. 4 shows an illustrative circuit diagram that may correspond to the illustrative block diagram of FIG. 3, in accordance with some embodiments of the present disclosure;

FIG. 5 shows a graphical representation of fitting a reference curve for isolation monitoring detection based on digital sampling of an amplified signal, in accordance with some embodiments of the present disclosure;

FIG. 6 shows an illustrative flowchart of a method for determining electrical isolation based on a fitted curve, in accordance with some embodiments of the present disclosure; and

FIG. 7 shows an illustrative flowchart of a method for isolation monitoring using adjustable gain amplifier, in accordance with some embodiments of the present disclosure.

### DETAILED DESCRIPTION

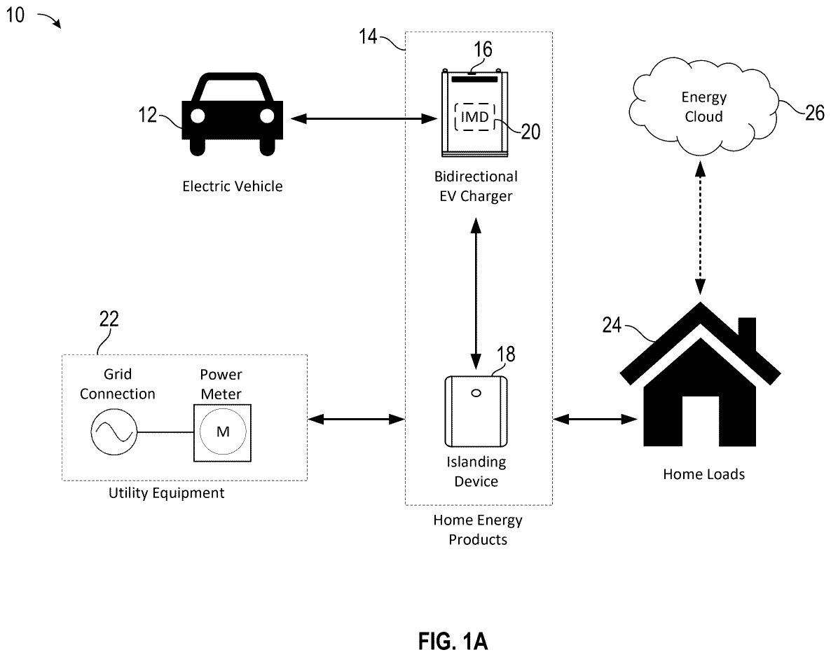

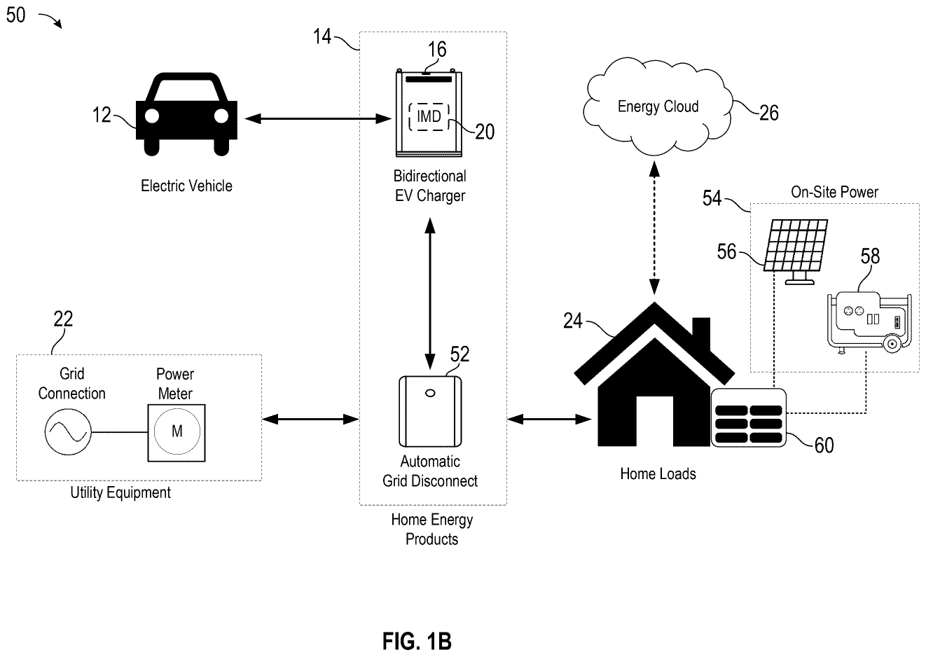

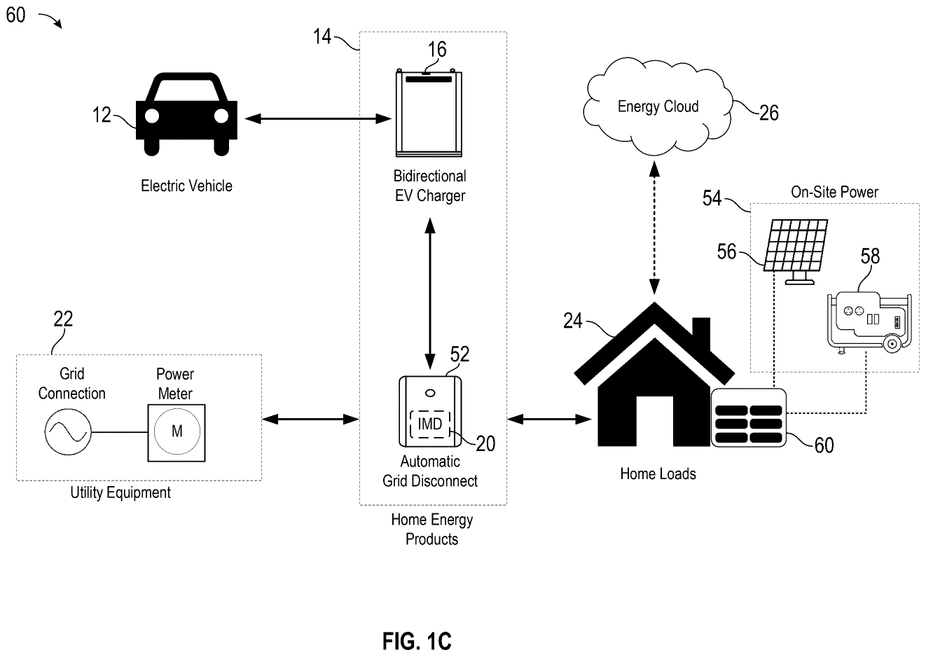

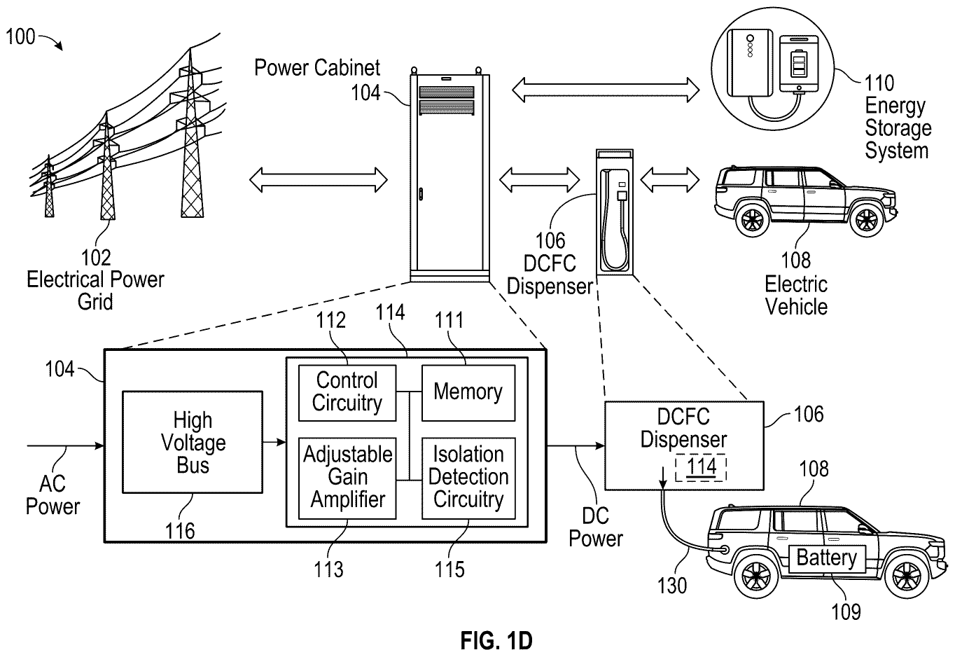

FIG. 1A depicts an illustrative block diagram of a residential electric vehicle charging system 10 including isolation monitoring device 20 and bidirectional charger 16, in accordance with some embodiments of the present disclosure. As shown, electric vehicle 12 is coupled to home energy products 14, which include at least bidirectional (BiDi) electric vehicle (EV) charger 16 and islanding device 18 (e.g., for islanding home loads 24 from utility equipment 22, including the grid connection therein). As shown, an isolation monitoring device (IMD) 20 (e.g., including isolation monitoring circuitry) may be included in BiDi EV charger 16. IMD 20 is further described below. Home energy products 14 are arranged between utility equipment 22 (e.g., including a grid connection and a power meter) and home loads 24. Home energy products 14 are configured to provide power from the grid (e.g., electrical power grid 102) to home loads 24, and/or to provide power from the grid to electric vehicle 12. Home energy products 14 are further configured, as per the capabilities of BiDI EV charger 16, to provide power from electric vehicle 12 to home loads 24, and/or to provide power form electric vehicle 12 to the grid. No matter the direction of power flow, BiDI EV charger 16, including IMD 20 therein, may determine that a high voltage bus (e.g., of electric vehicle 12, home loads 24, or the grid) is electrically isolated before allowing power to flow. Home loads 24 may be connected to energy cloud 26, e.g., such that energy cloud 26 can control a charging of electric vehicle 12 or a discharging of electric vehicle 12 (e.g., to provide power to home loads 24 or to the electric grid). For example, energy cloud 26 may determine a charging schedule to minimize electricity costs, or based on any suitable electricity indicator (e.g., to provide peak shaving, demand response, or other grid services).

FIG. 1B shows an illustrative block diagram depicting how on-site power generation equipment 54 can be added to the residential electric vehicle charging system of FIG. 1A, in accordance with some embodiments of the present disclosure. The resulting residential electric vehicle charging system 50 can, e.g., power electric vehicle 12 based on energy from solar panels 56, a generator 58, or any other suitable on-site power equipment. A power converter 60 may be connected to the on-site power generation equipment 54, e.g., to make power generated on-site suitable for powering home loads 24 and/or charging electric vehicle 12. Residential electric vehicle charging system 50 may, compared to residential electric vehicle charging system 10, replace islanding device 18 with automatic grid disconnect 52. Automatic grid disconnect 52 may be configured to automatically disconnect home loads 24 and electric vehicle 12 from the grid, e.g., based on instead receiving power from on-site power equipment 54.

In some embodiments, the residential electric vehicle charging system of FIG. 1A or of FIG. 1B provides home backup power by enabling power to flow from electric vehicle 12 to home loads 24. In place of or in addition to home loads 24, the systems of FIG. 1A and FIG. 1B may provide power to any other building or any associated electrical infrastructure, including, but not limited to, a branch circuit, an appliance, heating and/or cooling systems, electrical devices (e.g., phone, computer, modem, router, television, gaming console, etc.), lighting, another vehicle, a main panel, a subpanel, a breaker box, or even the electrical grid.

In electric vehicle charging applications, backup power applications, or other applications, IMD 20 determines whether electrical isolation is present before routing power between any source and any load. Therefore, IMD 20 can cause power to flow through intended electrical pathways and can prevent power from flowing through unintended electrical pathways.

FIG. 1C shows an illustrative block diagram depicting how an isolation monitoring device can be added to other equipment of the residential electric vehicle charging system of FIG. 1A, in accordance with some embodiments of the present disclosure. As shown in electric vehicle charging system 60 of FIG. 1C, IMD 20 may be provided within automatic grid disconnect 52 (or, based on the architecture of FIG. 1A, within islanding device 18), e.g., if it is convenient to collocate the IMD 20 and the automatic grid disconnect 52. Even if IMD 20 is provided within automatic grid disconnect 52 or within islanding device 18, rather than within BiDi EV charger 16, IMD 20 may still be configured to monitor for electrical isolation of the connection between electric vehicle 12 and BiDi EV charger 16. Moreover, IMD 20 could further determine whether there is electrical isolation between utility equipment 22 and home loads 24, between electric vehicle 12 and home loads 24, or between electric vehicle 12 and utility equipment 22, if IMD 20 is arranged as shown in FIG. 1C.

FIG. 1D depicts an illustrative block diagram an electric vehicle charging system 100 including isolation monitoring circuitry for providing power to a load and/or an energy storage system (ESS), in accordance with some embodiments of the present disclosure. Power is input to the system by electrical power grid 102, which is coupled to power cabinet 104, which may contain isolation monitoring circuitry 114. Power cabinet 104 is coupled to direct current fast charge (DCFC) dispenser 106, which may also contain isolation monitoring circuitry 114 (e.g., including memory 111, control circuitry 112, adjustable gain amplifier 113, and isolation detection circuitry 115 or isolation detection circuitry 300, where all components of isolation monitoring circuitry 114 are coupled to each other). Through a direct connection or through dispenser 106, power cabinet 104 ultimately delivers power (e.g., using a power electronics module (PEM), that is not shown) to at least one of electric vehicle 108 (specifically battery 109 therein) and/or energy storage system (ESS) 110, via high voltage bus 116, which is charged by the AC power from the grid (using additional circuitry not shown). Power cabinet 104 (and/or DCFC dispenser 106) includes isolation monitoring circuitry 114 to determine whether high voltage bus 116 is electrically isolated from a reference voltage (e.g., a ground potential of electrical power grid 102). Each of power cabinet 104 and DCFC dispenser 106 is enclosed within a housing, and charging cable 130 may extend from either of those housings. When there is electrical isolation, power flows through electric vehicle charging system 100 and to electric vehicle 108 (e.g., via charging cable 130) as intended.

In some embodiments, isolation monitoring circuitry 114 is also configured to determine whether battery 109 and/or ESS 110 is electrically isolated. Thus, isolation monitoring circuitry 114 may be configured to be electrically coupled to the power terminals of battery 109 and/or the power terminals of ESS 110.

In some embodiments, electric vehicle charging system 100 corresponds to residential electric vehicle charging system 10 or residential electric vehicle charging system 50. In some embodiments, electric vehicle 108 corresponds to electric vehicle 12. In some embodiments, isolation monitoring circuitry 114 corresponds to IMD 20. In some embodiments, power cabinet 104 and/or DCFC dispenser 106 execute operations that are similar to those of home energy products 14. In some embodiments, energy storage system 110 may be a component of on-site power equipment 54.

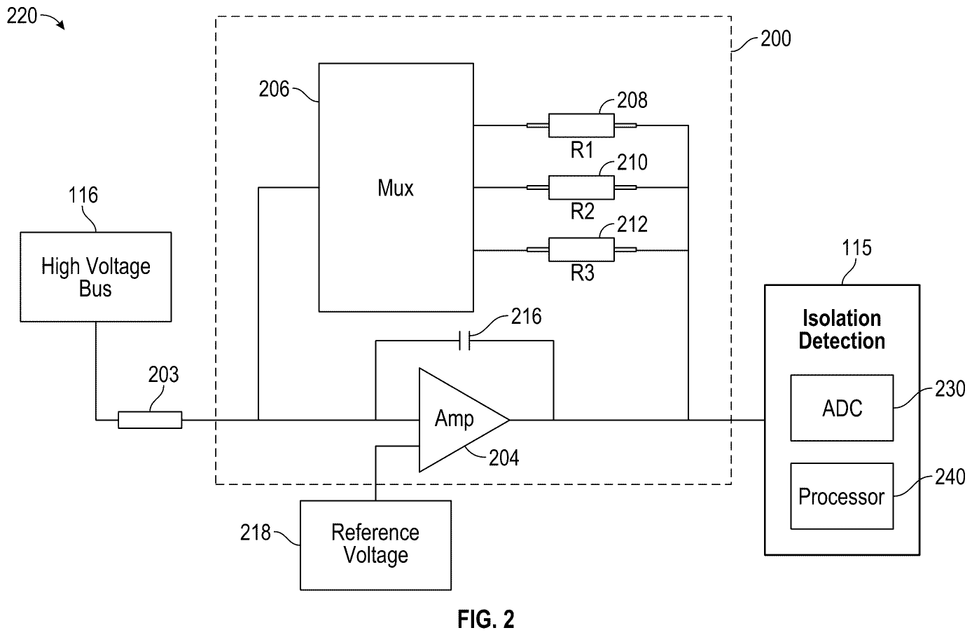

FIG. 2 shows an illustrative block diagram of circuitry 200 including an adjustable gain amplifier that amplifies a signal from a high voltage bus and provides the amplified signal to isolation detection circuitry, in accordance with some embodiments of the present disclosure. The circuitry 200 includes an amplifier 204, at least two resistors (or at least one adjustable resistor), and a multiplexer 206. In the illustrative depiction of FIG. 2, circuitry 200 includes three resistors, first resistor (R1) 208, second resistor (R2) 210, and third resistor (R3) 212. Because the resistors are arranged in a feedback configuration with amplifier 204, the feedback resistance controls the gain of the amplifier 204. Accordingly, multiplexer (mux) 206 selects at least one of resistors R1-R3 (e.g., by closing a switch that allows current to pass through the at least one resistor) to select a gain of the adjustable gain amplifier. Selecting the gain of the adjustable gain amplifier causes it to generate a corresponding amplified signal. The amplified signal is coupled to isolation detection circuitry 115, which is configured to determine, based on the amplified signal, whether high voltage bus 116 is electrically isolated.

A suitable resistance 203 (which may be a lumped resistance) resides between high voltage bus 116 and amplifier 204, such that the voltage of the high voltage bus 116 is sufficiently scaled down to within an operating range of amplifier 204 (e.g., the operating range based on a power supply voltage that powers amplifier 204).

Feedback capacitor 216 sets a time constant of amplifier 204 for fast operation (e.g., compared to the speed of ADC 230 of isolation detection circuitry 115, or otherwise compared to a desired “plug-to-charge” time associated with isolation detection circuitry 115).

Isolation monitoring circuitry 114 relates to certain components of FIG. 2 as follows. Multiplexer 206 may correspond to, or be a component of, control circuitry 112. Memory 111 may include memory that is coupled to (or stored within) multiplexer 206, e.g., causing multiplexer 206 to select a specific one of resistors R1-R3 (or to otherwise select a particular resistance value) based on a voltage of high voltage bus 116. Selecting a particular resistance value based on the voltage of high voltage bus 116 may include selecting the resistance value based on an input voltage to amplifier 204. Memory 111 may also be coupled to isolation detection circuitry 115, e.g., to provide instructions for determining whether high voltage bus 116 is isolated based on fitting the output of amplifier 204 to a reference voltage curve. Otherwise, isolation detection circuitry 115 may make that determination based on instructions stored in memory of processor 240. Adjustable gain amplifier 113 may include at least amplifier 204, capacitor 216, and resistors R1-R3 (or any other suitable device for providing a controllable feedback resistance across amplifier 204).

Isolation detection circuitry 115 may include at least ADC 230 and processor 240, as shown. ADC 230 may sample the output of amplifier 204, and processor 240 may be configured to determine whether high voltage bus 116 is electrically isolated based on the digitally sampled output. In some embodiments, processor 240 is configured to fit a reference curve to the digitally sampled output. Using the reference curve, processor 240 is further configured to determine an RC time constant, a Y capacitance, and an isolation resistance associated with the high voltage bus 116 (e.g., based on evaluating the system of equations provided below). Processor 240 may be configured to determine whether high voltage bus 116 is electrically isolated based on the isolation resistance (e.g., based on comparing the isolation resistance to one or more thresholds).

In some embodiments, multiple voltage ranges are stored in memory 111. Multiplexer 206 may be configured to select R1 when the input voltage to amplifier 204 is in a first range, to select R2 when the input voltage to amplifier 204 is in a second range, and to select R3 when the input voltage is in a third range. In one illustrative implementation, R3 has a greater resistance than R2, and R2 has a greater resistance than R1; accordingly, R3 is selected when the voltage is in a lowest range, R2 is selected when the voltage is in a middle range, and R1 is selected when the voltage is in a highest range.

The components shown in FIG. 2 may collectively be referred to as isolation monitoring system 220. Isolation monitoring system 220 may further include a relay to couple high voltage bus 116 to electric vehicle 108 and/or ESS 110 (e.g., to charge battery 109 or to charge a battery of ESS 110). Control circuitry 112 may be configured to cause that relay to close (e.g., to charge an electric vehicle) in response to a determination that the high voltage bus is electrically isolated. Isolation monitoring system 220 may be configured to detect for electrical isolation as soon as a charging cable is plugged into an electric vehicle (e.g., connecting the electric vehicle to power cabinet 104 and/or DCFC dispenser 106). Due to the operation of isolation monitoring system 220, “plug-to-charge” times can be reduced upon plugging in the charging cable. As used herein, the “plug-to-charge” time describes a delay, which is at least in part caused by determining that there is electrical isolation, between plugging in a cable and beginning to charge a battery.

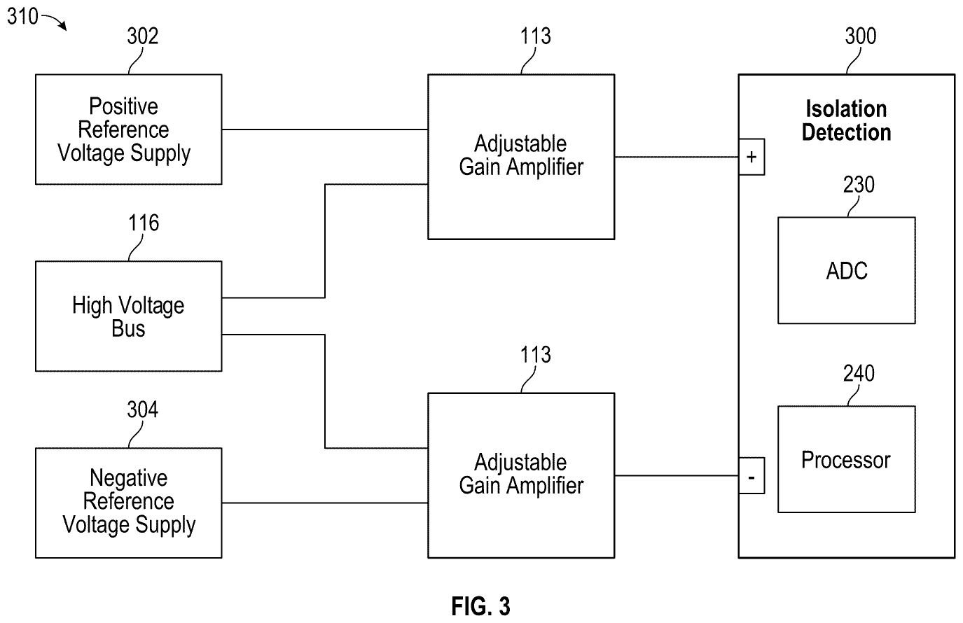

FIG. 3 shows an illustrative block diagram of isolation detection circuitry 300 configured to detect isolation based on positive and negative input signals, in accordance with some embodiments of the present disclosure. In some embodiments, isolation detection circuitry 115 is the same as isolation detection circuitry 300. However, isolation detection circuitry 300 may be slightly modified (e.g., having additional switches, or additional configurations of processor 240) from isolation detection circuitry 115 because isolation detection circuitry 300 operates on bipolar monitoring voltages, but isolation detection circuitry 115 need not operate on bipolar monitoring voltages. Isolation detection circuitry 300 fits two curves, one based on positive reference voltage supply 302 and the other based on negative reference voltage supply 304, to determine whether or not high voltage bus 116 is electrically isolated (e.g., from a ground reference voltage, which may be halfway between the positive reference voltage supply 302 and the negative reference voltage supply 304). In some embodiments, positive reference voltage supply 302 and negative reference voltage supply 304 are equal and opposite voltage levels.

The components shown in FIG. 3 may collectively be referred to as isolation monitoring system 310. As shown, isolation monitoring system 310 includes two adjustable gain amplifiers 113 (each of which may include, or be coupled to, control circuitry 112, including multiplexer 206, and optionally memory 111). However, in some embodiments, a typical (i.e., nonadjustable gain) amplifier may be used in connection with the bipolar isolation monitoring described herein. The first adjustable gain amplifier 113 provides a first amplified signal to a positive terminal of isolation detection circuitry 300, the first amplified signal being based on a comparison between positive reference supply voltage 302 (e.g., representing a positive polarity of a bipolar isolation monitoring) and high voltage bus 116. The second adjustable gain amplifier 113 provides a second amplified signal to a negative terminal of isolation detection circuitry 300, the second amplified signal being based on a comparison between negative reference supply voltage 304 (e.g., representing a negative polarity of a bipolar isolation monitoring) and high voltage bus 116.

Though not explicitly shown in FIG. 3, isolation monitoring system 310 may include any suitable switching scheme for coordinating the timing for isolation detection circuitry 300 to operate on two respective isolation monitoring signals based on two corresponding reference voltage supply signals.

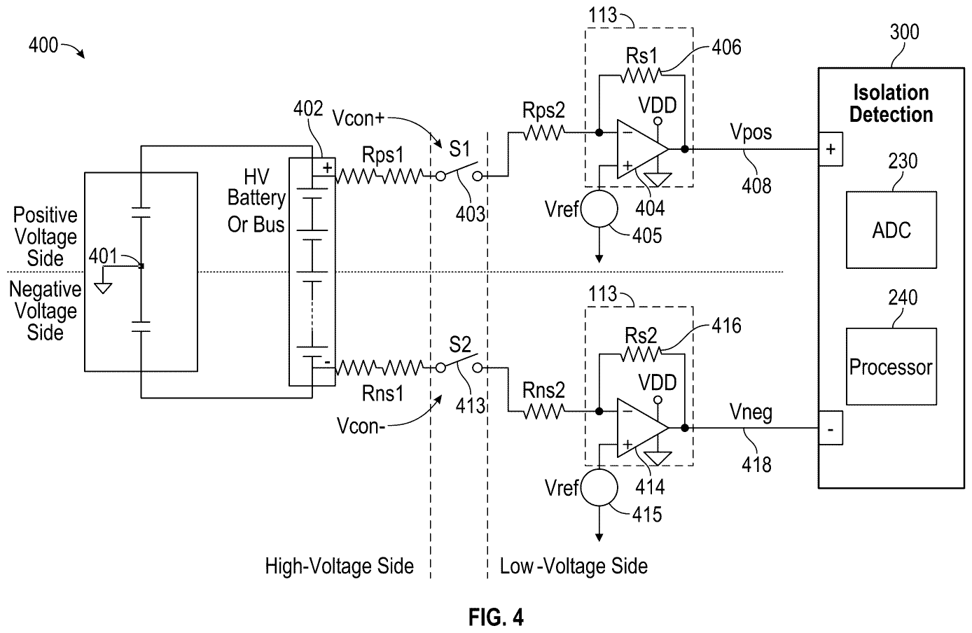

FIG. 4 shows an illustrative circuit diagram that may correspond to the illustrative block diagram of FIG. 3, in accordance with some embodiments of the present disclosure. That is, circuitry 400 shows one possible implementation of isolation monitoring system 310. In particular, circuitry 400 shows one possible switching topology for coordinating timing to perform isolation monitoring based on two isolation monitoring signals using a single instance of isolation detection circuitry 300 (e.g., using a single ADC).

Circuitry 400 includes a high voltage bus 402 (e.g., which may be battery 109, ESS 110, or high voltage bus 116). Respective (i.e., positive and negative) terminals of the high voltage bus 402 are electrically coupled to or electrically decoupled from isolation detection circuitry 300 based on the operation of switches 403 and 413. In some embodiments, switches 403 and 413 are controlled by control circuitry 112 (e.g., based on instructions stored in memory 111).

Switches 403 and 413 are controlled to be closed at different times. When switch 403 is closed (and switch 413 is open), positive monitoring voltage 408 is provided to a positive input of isolation detection circuitry 300. During this time, isolation detection circuitry 300 may fit a first reference voltage curve to positive monitoring voltage 408, where the first reference voltage curve is used to determine whether or not the positive terminal of high voltage bus 402 is electrically isolated (e.g., from ground voltage 401). When switch 413 is closed (and switch 403 is open), negative monitoring voltage 418 is provided to a negative input of isolation detection circuitry 300. During this time, isolation detection circuitry 300 may fit a second reference voltage curve to negative monitoring voltage 418, where the second reference voltage curve is used to determine whether or not the negative terminal of high voltage bus 402 is electrically isolated (e.g., from ground voltage 401). Isolation detection circuitry 300 may determine whether high voltage bus 402 is electrically isolated based on the first and second reference curves.

Circuitry 400 includes two adjustable gain amplifiers, though typical amplifiers may also be used in connection with bipolar isolation monitoring, as mentioned. The first adjustable gain amplifier includes first amplifier 404 and first resistor 406. The second adjustable gain amplifier includes second amplifier 414 and second resistor 416. Each of first resistor 406 and second resistor 416 may represent a single resistor that was selected (e.g., by respective control circuitry of the corresponding adjustable gain amplifier) from at least two resistors to configure respective gains of first amplifier 404 and second amplifier 414. Either, or both, of first adjustable gain amplifier and the second adjustable gain amplifier may be adjustable gain amplifier 113.

First amplifier 404 is connected to a first reference voltage 405 (e.g., which may correspond to the positive terminal of high voltage bus 402, and/or positive reference voltage supply 302). Second amplifier 414 is connected to a second reference voltage 415 (e.g., which may correspond to the negative terminal of high voltage bus 402, and/or negative reference voltage supply 304). First reference voltage 405 may be equal and opposite to second reference voltage 415. In some embodiments, first and second reference voltages may be, e.g., +/−1.5 V, +/−3 V, +/−5 V, or any other suitable range centered on 0 V. Otherwise, first reference voltage 405 may be a nonzero voltage and second reference voltage 415 may be a ground voltage, or vice versa. As annotated, the top portion of FIG. 4 may depict a positive voltage side of circuitry 400, and the bottom portion of FIG. 4 may depict a negative voltage side of circuitry 400

In some embodiments, first amplifier 404 is an operational amplifier configured to generate the positive monitoring voltage 408 to drive (e.g., based on feedback through first resistor 406) the input signal generated by closing switch 403 as close as possible to first reference voltage 405; the same can be true of second amplifier 414, accounting for the other signals and components on that branch of the circuit.

As annotated, the left portion of FIG. 4 may depict a relatively high voltage side of circuitry 400, and the right portion of FIG. 4 may depict a relatively low voltage side of circuitry 400. Suitable resistances (e.g., Rps1 and Rps2, or Rns1 and Rns2, where either pair may correspond to resistance 203) may be provided on one or both sides of the switches to scale down the relatively high voltage (e.g., 850 V, any other power supply voltage, or any other high-voltage battery voltage) to a relatively low volage (e.g., 5 V, or any other low-voltage that is suitable for operating isolation detection circuitry 300, among other low-power electronics).

As shown in FIG. 4, the capacitance values on either side of the ground voltage 401 may represent respective capacitance values associated with the Y capacitance of the high voltage bus 402.

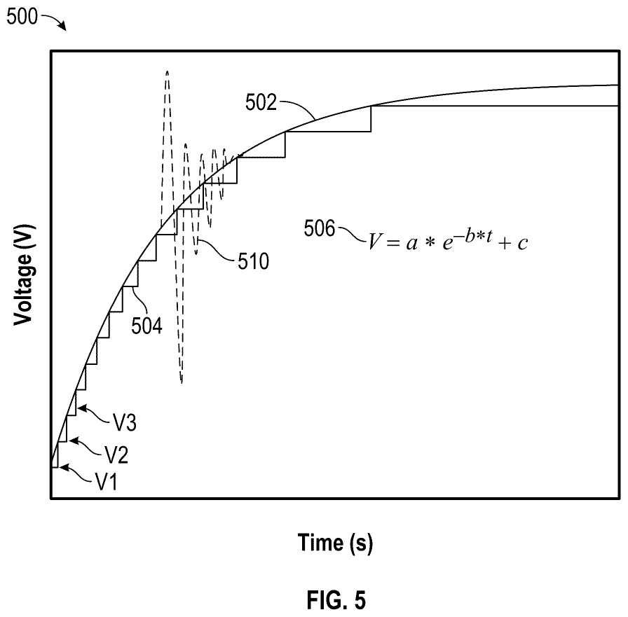

FIG. 5 shows a graphical representation 500 of fitting a reference curve 502 for isolation monitoring detection based on digital sampling of an amplified signal 504, in accordance with some embodiments of the present disclosure. For example, amplified signal 504 may be a digital sampling (e.g., by ADC 230 of isolation detection circuitry 115) of the output of adjustable gain amplifier 113. That is, amplified signal 504 may be a digital representation of positive monitoring voltage 408 or negative monitoring voltage 418.

In some embodiments, ADC 230 begins sampling the output of adjustable gain amplifier 113 in response to a command (e.g., from control circuitry 112) to close a switch (e.g., either of switches 403 or 413). Amplified signal 504 is initially recorded as digital voltage levels V1, V2, and V3, in that order, as shown in the staircase shape of amplified signal 504. In some embodiments, digital voltage levels V1, V2, and V3 represent the first three uniquely valued samples of an ADC of isolation detection circuitry 115.

Isolation detection circuitry 115 may further include a processor 240 configured to fit reference voltage curve 502 to the at least three uniquely valued samples of amplified signal 504, based on equation 506. Equation 506 may describe how an exponential voltage V varies with time t using the coefficients a, b, and c, as described by equations (1-3)

$$b = ln ( \frac{( {V}_{3} - {V}_{2} )}{{V}_{2} - {V}_{1}} ) * ( - \frac{1}{dT} ) \qquad ( 1 )$$

$$a = ( {V}_{2} - {V}_{1} ) * ( \frac{1}{{e}^{- b ⋆ dT} - 1} ) \qquad ( 2 )$$

$$c = {V}_{1} - a \qquad ( 3 )$$

where dT is a timing interval between respective voltage measurements, V1 is a first voltage (e.g., an initial voltage measured upon closing a switch), V2 is a second voltage, and V3 is a third voltage (e.g., the first, second, and third, respectively of the three unique valued samples). In some embodiments, respective measurement times associated with V1, V2, and V3 are equally spaced apart from each other, and dT is equal to n*Tₛₐₘₚ, where n is a number of samples between V1 and V2 (or, equivalently, between V2 and V3), and Tₛₐₘₚ is a sampling rate of ADC 230. For example, V1, V2, and V3 of equations (1-3) may be the voltage levels as annotated in graphical representation 500. In some embodiments, V1 is an initial voltage (e.g., at time t=0, which may coincide with closing switch 403 or switch 413), V2 is a voltage at time t=n*Tₛₐₘₚ (where n is any suitable integer, e.g., which causes there to be a sufficient delay between V1 and V2 so that those digitized voltage levels are different), and V3 is a voltage at time t=2n*Tₛₐₘₚ.

Operations of the processor 240 may include: (i) fitting reference curves to the positive and negative monitoring voltages; (ii) determining DC values of the reference curves (e.g., the values to which the reference voltage curve 502 settles to); (iii) solving a system of equations, including calculating an RC time constant, a Y capacitance, and an isolation resistance; and (iy) comparing the isolation resistance to a threshold.

In connection with operations (iii) of the processor 240, the system of equations may include equations (4-5) as shown below:

$${V}_{{ISO}_{POS}} = {V}_{REF} - \frac{( ( 1 - D ) {V}_{HVDC} - {V}_{REF} ) * {R}_{S 1}}{{R}_{ps 1} + {R}_{ps 2} + {R}_{iso}} \qquad ( 4 )$$

$${V}_{{ISO}_{NEG}} = {V}_{REF} + \frac{( D * {V}_{HVDC} - {V}_{REF} ) * {R}_{S 2}}{{R}_{ns 1} + {R}_{ns 2} + {R}_{iso}} \qquad ( 5 )$$

where equation (4) solves for the positive monitoring voltage 408 and equation (5) solves for the negative monitoring voltage 418. In equations (4-5), V_{REF} is the corresponding one of reference voltages 405 and 415, D is a scalar that is set as 0 when there is a fault on the negative terminal of high voltage bus 402 and that is set as 1 when there is a fault on the positive terminal of high voltage bus 402), V_{HVDC} is a voltage level of high voltage bus 402 (e.g., a difference between the positive terminal and ground, or a difference between the negative terminal and ground), R_{S1}, and RS_{S2} are the resistances of switches 403 and 413, respectively, and Rₚₛ₁, Rₚₛ₂, Rₙₛ₁, and Rₙₛ₂ are the resistances as shown and annotated in FIG. 4.

In connection with operations (iii) of the processor 240, the system of equations may also include equations (6-8) as shown below:

$${C}_{{Y}_{tot}} = \frac{\frac{1}{{R}_{pn}} + \frac{1}{{R}_{iso}}}{b} \qquad ( 6 )$$

$$D = \frac{( {V}_{{ISO}_{NEG}} ( {V}_{HVDC} - {V}_{{ref}_{p}} ) )}{{V}_{HVDC} ( {V}_{{ISO}_{NEG}} - {V}_{{ISO}_{POS}} + {V}_{{ref}_{p}} )} \qquad ( 7 )$$

$${R}_{iso} = - \frac{( {R}_{pn} {V}_{{ISO}_{NEG}} - {R}_{s} {V}_{HVDC} - {R}_{pn} {V}_{{ISO}_{POS}} + {R}_{pn} {V}_{{ref}_{p}} + {R}_{s} {V}_{{ref}_{p}} )}{{V}_{{ISO}_{NEG}} - {V}_{{ISO}_{POS}} + {V}_{{ref}_{p}}} \qquad ( 8 )$$

where C_{Ytot} is the total Y capacitance of high voltage bus 402, Rₚₙ is the sum of Rₚₛ₁, Rₚₛ₂ (or, equivalently, of Rₙₛ₁, and Rₙₛ₂), V_{refp} is a reference voltage (e.g., reference voltage 405, reference voltage 415, or a value corresponding to the absolute values of both those reference voltages), Rₛ is the resistance of switch 403 (or, equivalently, of switch 413), and the other values are as described in connection with equations (1-5).

Based on calculating at least the DC volage levels and the RC time constants of positive monitoring voltage 408 and negative monitoring voltage 418 (e.g., as per the curve fitting of reference curve 502 using equation 506, which is illustrative of both monitoring voltages), the system of equations (4-8) may be solved to determine the isolation resistance. Processor 240 may be configured to determine that high voltage bus 402 is isolated if the isolation resistance is below a threshold (e.g., 100 kOhm). The threshold may be set, e.g., based on the tolerance of power delivery equipment, based on a voltage of the high voltage bus 116, or based on any other suitable standard or consideration.

In some embodiments, an arc event occurs, as shown by trace 510. During the arc event, the analog output level swings around the exponential shape of reference curve 502. Though not shown, if sampling at a sufficiently fast rate (e.g., compared to the oscillations of the arc event), then amplified signal 504 would similarly swing. If processor 240 detected this output level swing (e.g., based on a change in slope, a decrease, or any other characteristic in amplified signal 504), then it may be configured to determine that an arc event has occurred. For example, processor 240 may be configured to determine that an arc event has occurred based on a failure to fit any three uniquely valued samples of ADC 230 to the reference curve.

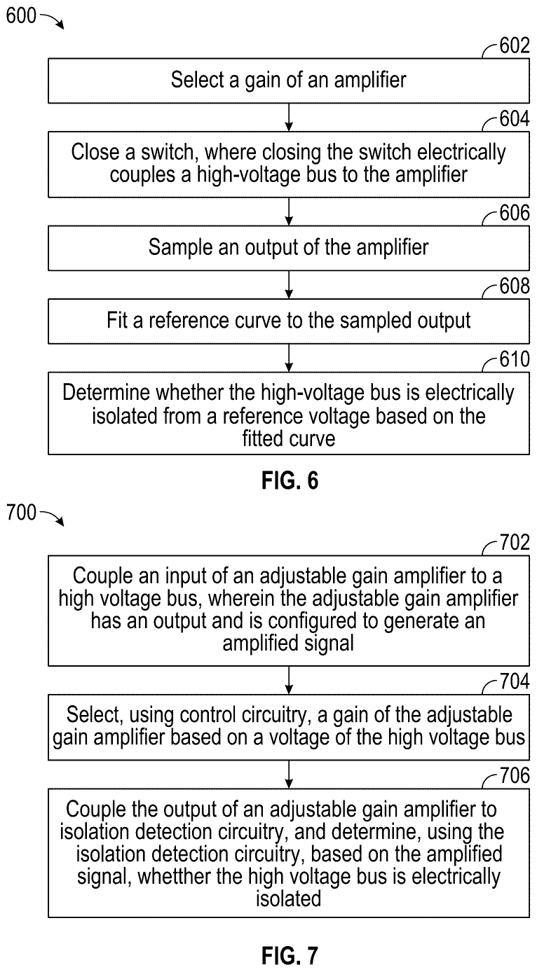

FIG. 6 shows an illustrative flowchart of a method 600 for determining electrical isolation based on a fitted curve, in accordance with some embodiments of the present disclosure. For example, method 600 may be performed by any suitable processing circuitry (e.g., which may be control circuitry 112, ADC 230, processor 240, isolation detection circuitry 115, isolation detection circuitry 300, any other suitable circuitry, or any combination thereof).

At step 602, method 600 includes selecting a gain of an amplifier (e.g., adjustable gain amplifier 113). Selecting the gain may include causing multiplexer 206 to route an input signal through one of multiple possible feedback resistors (e.g., any of R1-R3 as shown in FIG. 2) based on a voltage of the input signal to the amplifier.

At step 604, method 600 includes closing a switch (e.g., switch 403 or switch 413), where closing the switch electrically couples a high voltage bus (e.g., high voltage bus 116, or high voltage bus 402) to the amplifier. Step 604 may include controllably closing multiple switches (e.g., switch 403 and switch 413), such that at most one of the switches is closed at any given time.

At step 606, method 600 includes sampling (e.g., using ADC 230) an output of the amplifier. Sampling the output of the amplifier may include generating at least three voltage samples (e.g., V1, V2, and V3 as shown in FIG. 5). The samples may represent discrete levels of amplified signal 504 (e.g., each of the samples is uniquely valued with respect to the others).

At step 608, method 600 includes fitting a reference curve to the sampled output. For example, fitting the reference curve may include solving equations (1-3) based on the at least three voltage samples, to generate a reference curve 502 that is fit to the amplified signal 504.

At step 610, method 600 includes determining whether the high-voltage bus is electrically isolated from a reference voltage (e.g., a ground voltage) based on the fitted curve. Determining whether the high-voltage bus is electrically isolated may include solving equations (4-8) based on the operations of step 608 to determine an isolation resistance. Step 610 may also include determining that the high-voltage bus is electrically isolated when the isolation resistance is above a threshold.

In some embodiments, method 600 includes, before step 610, repeating at least steps 604-608 for positive and negative branches of isolation monitoring detection circuitry (e.g., as shown and described at least in connection with FIG. 4). Accordingly, at step 610, signals from both branches may be used to determine whether the high-voltage bus is electrically isolated. For example, signals from both branches may be used when solving equations (4-8).

FIG. 7 shows an illustrative flowchart of a method 700 for isolation monitoring using adjustable gain amplifier, in accordance with some embodiments of the present disclosure. For example, method 700 may be performed by isolation monitoring circuitry 114 (e.g., by processing circuitry thereof, where the processing circuitry may include control circuitry 112, ADC 230, processor 240, isolation detection circuitry 115, isolation detection circuitry 300, any other suitable circuitry, or any combination thereof).

At step 702, method 700 includes coupling an input of an adjustable gain amplifier (e.g., adjustable gain amplifier 113) to a high voltage bus (e.g., high voltage bus 116), where the adjustable gain amplifier has an output and is configured to generate an amplified signal (e.g., positive monitoring voltage 408 or negative monitoring voltage 418, either of which may be digitized into amplified signal 504).

At step 704, method 700 includes selecting, using control circuitry (e.g., control circuitry 112, which may include multiplexer 206) a gain of the adjustable gain amplifier based on a voltage of the high voltage bus. For example, basing the gain on the voltage of the high voltage bus may include basing the gain on the input voltage to the adjustable gain amplifier (e.g., because that input voltage is coupled to the high voltage bus). The control circuitry may select a particular gain according to instructions stored in memory 111. The instructions may, e.g., map nonoverlapping voltage ranges to respective resistors (or resistor combinations, to create a parallel resistance) for which the multiplexer should close a corresponding switch. Closing the switch may provide a feedback path through the selected resistor and across an amplifying device (e.g., amplifier 204) of the adjustable gain amplifier.

At step 706, method 700 includes coupling the output of an adjustable gain amplifier to isolation detection circuitry (e.g., isolation detection circuitry 115, or isolation detection circuitry 300), and determining, using the isolation detection circuitry (e.g., using ADC 230 and processor 240), based on the amplified signal, whether the high voltage bus is electrically isolated (e.g., from a ground voltage or another reference voltage associated with a power grid).

In some embodiments, step 704 may correspond to step 602. In some embodiments, step 706 may include some or all of steps 604-610.

In some embodiments, method 700 also includes closing a relay in response to a determination that the high voltage bus is electrically isolated. Closing the relay couples the high voltage bus to an electric vehicle, thereby causing the electric vehicle to be charged. In some embodiments, the equipment involved in method 700 is enclosed within a housing (e.g., surrounding power cabinet 104, or surrounding DCFC dispenser 106), and a charging cable (e.g., charging cable 130) extends from the housing. The charging cable is configured to be coupled to an electric vehicle. Method 700 may also include charging the electric vehicle through the charging cable (e.g., based on determining that the high voltage bus is electrically isolated and therefore closing the relay). Method 700 may also include, while charging the vehicle, repeatedly making the determination at step 706 (and optionally the selection at step 704). In response to a determination that the high voltage bus is not still electrically isolated, method 700 may also include disconnecting the electric vehicle (e.g., based on opening the relay) from the high voltage bus.

In some embodiments, method 700 also includes determining that an arc event has occurred based on a measurement and/or calculation made when determining whether the high voltage bus is electrically isolated. Method 700 may also include, in response to determining that an arc event has occurred, generating an alert of the arc event (e.g., where the alert may be communicated to electric vehicle 108, to power cabinet 104, to a network operator, to an owner/operator of any of the aforementioned equipment, or to any combination thereof).

The processes described above are intended to be illustrative and not limiting. One skilled in the art would appreciate that the steps of the processes described herein may be omitted, modified, combined and/or rearranged, and any additional steps may be performed without departing from the scope of the invention.

The foregoing is merely illustrative of the principles of this disclosure, and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations thereto and modifications thereof, which are within the spirit of the following claims.

What is claimed is:

1. A system comprising:
a high voltage bus;
an adjustable gain amplifier having an input coupled to the high voltage bus and having an output, wherein the adjustable gain amplifier is configured to generate an amplified signal;
control circuitry configured to select a gain of the adjustable gain amplifier based on a voltage of the high voltage bus; and
isolation detection circuitry coupled to the output of the adjustable gain amplifier and configured to determine, based on the amplified signal, whether the high voltage bus is electrically isolated.

2. The system of claim 1, wherein the adjustable gain amplifier comprises a multiplexer and a plurality of resistors, wherein the control circuitry is configured to cause the multiplexer to:
select a first resistor of the plurality of resistors when the voltage is in a first range; and
select a second resistor of the plurality of resistors when the voltage is in a second range, the second resistor having a greater resistance than the first resistor and the second range being less than the first range.

3. The system of claim 2, wherein the control circuitry is further configured to cause the multiplexer to select a third resistor of the plurality of resistors when the voltage is in a third range, the third resistor having a greater resistance than the second resistor and the third range being less than the second range.

4. The system of claim 1, further comprising a relay, wherein the control circuitry is configured to cause the relay to couple the high voltage bus to an electric vehicle in response to a determination that the high voltage bus is electrically isolated.

5. The system of claim 1, wherein:
the adjustable gain amplifier is a first adjustable gain amplifier, the amplified signal is a first amplified signal, the control circuitry is first control circuitry, and the first adjustable gain amplifier and the first control circuitry are coupled to a first supply voltage;
the system further comprises a second adjustable gain amplifier configured to generate a second amplified signal, and second control circuitry coupled to the high voltage bus and coupled to a second supply voltage, equal and opposite to the first supply voltage; and
the isolation detection circuitry is further configured to determine whether the high voltage bus is electrically isolated based on the second amplified signal.

6. The system of claim 1, wherein the isolation detection circuitry comprises:
an analog-to-digital converter (ADC) configured to sample the amplified signal of the adjustable gain amplifier; and
processing circuitry configured to fit a reference curve to at least three samples of the ADC, wherein determining whether the high voltage bus is electrically isolated is based on the fitted reference curve.

7. The system of claim 6, wherein the at least three samples of the ADC are selected as a first three uniquely valued samples of the ADC.

8. The system of claim 6, wherein the processing circuitry is further configured to determine that an arc event has occurred based on a failure to fit the at least three samples of the ADC to the reference curve.

9. A method comprising:
coupling an input of an adjustable gain amplifier to a high voltage bus, wherein the adjustable gain amplifier has an output and is configured to generate an amplified signal;
selecting, using control circuitry, a gain of the adjustable gain amplifier based on a voltage of the high voltage bus; and
coupling the output of the adjustable gain amplifier to isolation detection circuitry, and determining, using the isolation detection circuitry, based on the amplified signal, whether the high voltage bus is electrically isolated.

10. The method of claim 9, wherein the adjustable gain amplifier comprises a multiplexer and a plurality of resistors, and wherein selecting the gain comprises causing the multiplexer to:
select a first resistor of the plurality of resistors when the voltage is in a first range; and
select a second resistor of the plurality of resistors when the voltage is in a second range, the second resistor having a greater resistance than the first resistor and the second range being less than the first range.

11. The method of claim 10, wherein selecting the gain further comprises causing the multiplexer to select a third resistor of the plurality of resistors when the voltage is in a third range, the third resistor having a greater resistance than the second resistor and the third range being less than the second range.

12. The method of claim 9, further comprising causing, using the control circuitry, a relay to couple the high voltage bus to an electric vehicle in response to a determination that the high voltage bus is electrically isolated.

13. The method of claim 9, wherein:
the adjustable gain amplifier is a first adjustable gain amplifier, the amplified signal is a first amplified signal, the control circuitry is first control circuitry, and the first adjustable gain amplifier and the first control circuitry are coupled to a first supply voltage; the method further comprising:
selecting, using second control circuitry, a gain of a second adjustable gain amplifier based on the voltage of the high voltage bus, wherein the second adjustable gain amplifier is configured to generate a second amplified signal, is coupled to the high voltage bus, and is coupled to a second supply voltage, equal and opposite to the first supply voltage; wherein:
the determining whether the high voltage bus is electrically isolated is further based on the second amplified signal.

14. The method of claim 9, wherein determining whether the high voltage bus is electrically isolated comprises:
sampling, using an analog-to-digital converter (ADC), the amplified signal of the adjustable gain amplifier; and
fitting a reference curve to at least three samples of the ADC, wherein:
determining whether the high voltage bus is electrically isolated is based on the fitted reference curve.

15. The method of claim 14, wherein the at least three samples are selected as a first three uniquely valued samples of the ADC.

16. The method of claim 14, further comprising determining that an arc event has occurred based on a failure to fit the at least three samples to the reference curve.

17. An electric vehicle charger comprising:
a housing comprising:
a high voltage bus,
an adjustable gain amplifier having an input coupled to the high voltage bus and an output, wherein the adjustable gain amplifier is configured to generate an amplified signal,
control circuitry configured to select a gain of the adjustable gain amplifier based on a voltage of the high voltage bus, and
isolation detection circuitry coupled to the output of the adjustable gain amplifier and configured to determine, based on the amplified signal, whether the high voltage bus is electrically isolated; and
a charging cable extending from the housing, wherein the charging cable is configured to be coupled to an electric vehicle and to charge the electric vehicle in response to a determination that the high voltage bus is electrically isolated.

18. The electric vehicle charger of claim 17, further comprising a relay, wherein the relay is configured to couple the high voltage bus to the electric vehicle and to cause the electric vehicle to be charged in response to a determination that the high voltage bus is electrically isolated.

19. The electric vehicle charger of claim 17, wherein the control circuitry is further configured to, while charging the electric vehicle, and in response to a determination that the high voltage bus is not still electrically isolated, disconnect the electric vehicle from the high voltage bus.

20. The electric vehicle charger of claim 17, wherein the isolation detection circuitry is further configured to determine, based on the amplified signal, whether an arc event has occurred.
